(19) United States
(12) Patent Application Publication
(10) Pub. No.: US 2022/0195580 A1
(43) Pub. Date: Jun. 23, 2022

(54) METHOD FOR DEPOSITING AN ORGANIC OR HYBRID ORGANIC/INORGANIC PEROVSKITE LAYER

(71) Applicant: Commissariat a L'Energie Atomique Et Aux Energies Alternatives, Paris (FR)

(72) Inventors: Louis Grenet, Grenoble (FR); Fabrice Emieux, Grenoble (FR); Jean-Marie Verilhac, Grenoble (FR)

(21) Appl. No.: 17/644,976

(22) Filed: Dec. 17, 2021

(30) Foreign Application Priority Data
Dec. 21, 2020 (FR) 2013841

(51) Int. Cl. C23C 14/24; C23C 14/12; G01T 1/202

(52) U.S. Cl. CPC C23C 14/24; H01L 27/308; G01T 1/2023; C23C 14/12

(57) ABSTRACT

Method for depositing an organic or hybrid organic/inorganic perovskite layer on a substrate comprising the following steps: a) providing a substrate and an organic or hybrid organic/inorganic target, b) positioning the substrate and the target, in a close space sublimation furnace, c) depositing an organic or hybrid organic/inorganic perovskite layer on the substrate by sublimation of the target, the temperature difference between the target and the substrate being, preferably, comprised between 50° C. and 350° C., even more preferentially between 50° C. and 200° C., the thickness of the deposited organic or hybrid organic/inorganic perovskite layer being, preferably, comprised between 50 nm and 5000 μm.

### CROSS-REFERENCE TO RELATED APPLICATIONS

This application claims priority from French Patent Application No. 2013841 filed on Dec. 21, 2020. The contents of this application is incorporated herein by reference in its entirety.

### TECHNICAL FIELD

The present invention pertains to the general field of methods for depositing organic or hybrid organic/inorganic perovskite layers.

The invention finds applications in numerous industrial fields, in particular in the field of X-ray detection for medical, safety, security, radioprotection, or large scientific instruments, but also in the field of photovoltaics, the detection of gamma radiation, ionising radiation (alpha, beta, neutron) or instead for the manufacture of electronic, optical or optoelectronic devices, in particular for the manufacture of light emitting diodes (LEDs), photodetectors, scintillators or transistors.

The invention is particularly interesting since it makes it possible to deposit perovskite layers in a very wide range of thicknesses, ranging from thin layers (thickness typically comprised between 10 nm and 10 μm) to thick layers (thickness typically greater than or equal to 10 μm or even greater than 1 mm). A good control of the quality of the layers for reasonable deposition times (>6 h) is possible in the thickness range 10 nm-5 mm.

### PRIOR ART

Organic or hybrid organic/inorganic perovskite (PVK) materials of ABX₃ type are particularly interesting for applications in the field of photovoltaics (PV), LEDs, photodetectors in the ranges of the visible or near infrared, or for the detection of X-rays and gamma rays.

These hybrid materials may be obtained by numerous methods [1]: growth in solution, deposition by spin coating, pulsed laser deposition (PLD), sequential vapour deposition (SVD), chemical bath deposition (CBD), etc.

Among these methods, it is for example possible to synthesise perovskite crystals of formula MAPbBr₃ according to the following steps: dissolving CH₃NH₃Br and PbBr₂ precursors in DMF under ultrasounds, filtering the solution thus obtained, then placing the filtrate in an oil bath at 80° C. for 4 h [2].

Crystals of formula ODABCO-NH₄Cl₃, ODABCO-NH₄Br₃ and MDABCO-NH₄I₃ have also been synthesised by slow evaporation, over several days, of a solution containing the precursors of these materials [3].

According to another example, hybrid organic/inorganic perovskites of formula AMX₃ may be obtained by close space sublimation (CSS) [4]. To do so, it is necessary firstly to deposit, on a substrate, a layer of inorganic precursor MX₂ with X a halide ion and M a cation of a divalent metal, and providing a source A of organic material (for example CH₃NH₃⁺). The precursor layer has a thickness, for example, of 30 nm to 500 nm. The source has, for example, a thickness of 1 mm. Then the precursor layer and the source are heated. Alone, the organic part is sublimated. The perovskite material is obtained by solid diffusion of the organic part into the inorganic precursors.

However, with such a method, it is not possible to form thick perovskite layers.

### DESCRIPTION OF THE INVENTION

An aim of the present invention is to propose a method for depositing an organic or hybrid organic/inorganic perovskite layer, on a substrate, the method being simple to implement, making it possible to form layers of variable thickness (typically from ten or so nanometres to thicknesses greater than or equal to 5 mm), homogeneous both within the thickness and on the surface, over large surface areas, in a reasonable time (less than one day and preferably less than 6 h).

To do so, the present invention proposes a method for depositing an organic or hybrid organic/inorganic perovskite layer comprising the following steps:
providing a substrate and an organic or hybrid organic/inorganic target,
b) positioning the substrate and the target, in a close space sublimation furnace,
c) depositing an organic or hybrid organic/inorganic perovskite layer on the substrate by sublimation of the target.

The invention distinguishes itself from the prior art by the deposition of a layer of a completely organic or hybrid organic/inorganic perovskite material by close space sublimation (CSS) in a single step. Since the material of the target comprises all the elements of the perovskite that it is wished to obtain, there is not necessarily need to form a precursor layer on the substrate.

The perovskite layers thus obtained have a uniform thickness and homogeneous characteristics over the entire deposition surface. The method is reproducible and may be used to deposit perovskite layers on surfaces of varied dimensions, for example from 1 cm² to more than 1 m².

As a function of the deposition duration and temperature, it is possible to obtain layers of high thicknesses (typically greater than or equal to 0.1 mm, for example from 0.1 mm to 3 mm, or even from 0.1 mm to 5 mm), of intermediate or moderate thicknesses (typically from 2 μm to less than 0.1 mm) or instead of low thicknesses (typically less than 2 μm).

This method is particularly interesting for depositing thick layers (typically of thicknesses greater than or equal to 0.1 mm) having to be implemented at moderate temperatures (typically less than 250° C.).

Advantageously, the organic or hybrid perovskite layer has a thickness comprised between 50 nm and 5000 μm. For example, for applications of PV, LED, IR detection type, the targeted thicknesses will be of the order of several tens of nanometres to ten or so micrometres (typically from 50 nm to 10000 nm), whereas for the detection of X-rays and gamma rays, the targeted thicknesses will be of the order of several tens of micrometres to several thousands of micrometres (from 10 μm to 5000 am).

According to a first advantageous alternative embodiment, the organic or hybrid organic/inorganic perovskite layer has for formula ABX₃.

A is an organic compound, a mixture of organic compounds or a mixture of organic compound and inorganic compound. Organic compound is taken to mean any compound containing at least the element carbon and one or more of the following elements: hydrogen, halogen, oxygen, sulphur, phosphorous, silicon or nitrogen.

For example, A represents:

an organic molecule: for example CH₃NH₃⁺ (methylammonium MA) or CH(NH₂)₂⁺ (formamidinium FA), or C(NH₂)₃⁺ (guanidinium GA)

a mixture of organic molecules (for example: MA₁₋ₓFAₓ with 0<x<1), or

a mixture of organic (for example MA, FA) and inorganic (for example Cs, Rb, K, Li, Na, etc.), (for example: Cs₁₋ₓFAₓ with 0<x<1) parts,

B a single inorganic element (for example Pb, Sn, Ge, Si, etc.), an organic molecule (such as N-methyl-1,4-diazabicyclo[2.2.2]octane) (MDABCO) or N-hydroxy-N′-diazabicyclo[2.2.2]octonium (ODABC)), a mixture of several inorganic elements (for example an alloy such as Sn_{0.5}Pb_{0.5}) and/or organic molecules,

X an anion, preferably a halide (for example X═Cl⁻, Br⁻, I⁻, F, etc.). According to this first alternative embodiment, the organic or hybrid organic/inorganic perovskite layer is, preferably, made of MAPbBr₃.

Even more preferentially, the perovskite layer is made of MAPbBr₃ and has a thickness comprised between 500 μm and 2 mm.

According to these different alternative embodiments, it is also possible to have mixtures of 2 to 5 elements on each X site (for example of the type X═ClₖBrₗIₖ₋ₗ with 0≤k, l≤1 and 0≤k+l≤1). The same is true for the A and B sites.

A generalisation may be made by stating that the organic or hybrid organic/inorganic perovskite layer has for formula A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ. The organic or hybrid organic/inorganic perovskite layer has, for example, for formula Cs_{0.17}FA_{0.83}Pb(Br_{0.17}I_{0.83})₃.

According to a second advantageous alternative embodiment, the organic or hybrid organic/inorganic perovskite layer has for formula A₂C¹⁺D³⁺X₆.

with A an organic compound, a mixture of organic compounds or a mixture of organic compound and inorganic compound such as defined previously,

C and D are cations. C may be selected, for example, from among Ag, Au, TI, Li, Na, K, Rb and/or D may be selected, for example, from among Al, Ga, In, Sb, Bi.

X is an anion, preferably a halide (for example X═Cl⁻, Br⁻, I⁻, F⁻, etc.).

According to this second alternative embodiment, the organic or hybrid organic/inorganic perovskite layer has, preferably, for formula MA₂AgBiBr₆.

According to a third alternative embodiment, the organic or hybrid organic/inorganic perovskite layer is of Ruddlesden-Popper type also commonly called 2D perovskites, with for example the formula (RNH₃)₂Aₙ₋₁BₙX₃ₙ₊₁ (n=1, 2, 3, 4, etc.), with R an aliphatic and/or aromatic carbon chain, and

A:

an organic molecule: for example CH₃NH₃⁺ (methylammonium MA) or CH(NH₂)₂⁺ (formamidinium FA), or C(NH2)3⁺ (guanidinium GA)

a mixture of organic molecules (for example: MA₁₋ₓFAₓ with 0<x<1), or

a mixture of organic (for example MA, FA) and inorganic (for example Cs, Rb, K, Li, Na, etc.), (for example: Cs₁₋ₓFAₓ with 0<x<1) parts,

B:

a single inorganic element (for example Pb, Sn, Ge, Si, etc.), an organic molecule (such as N-methyl-1,4-diazabicyclo[2.2.2]octane) (MDABCO) or N-hydroxy-N′-diazabicyclo[2.2.2]octonium (ODABC)), a mixture of several inorganic elements (for example an alloy such as Sn_{0.5}Pb_{0.5}) and/or organic molecules,

X:

X an anion, preferably a halide (for example X═Cl⁻, Br⁻, I⁻, F⁻, etc.).

According to a particular embodiment, the target is formed of particles.

According to an alternative of this particular embodiment, the target comprises particles of formula ABX₃.

According to another alternative of this particular embodiment, the target comprises a mixture of binary particles of different natures, for example a MABr, BiBr₃ and AgBr mixture, the mixture further being able to comprise tertiary particles, for example the target comprises particles of formula AX, particles of formula BX₂ and optionally particles of formula ABX₃.

According to an advantageous embodiment, the target is a solid target, formed of agglomerated and/or sintered particles. This alternative makes it possible to manufacture perovskite layers of low, medium or high thicknesses. This alternative is particularly advantageous for forming perovskite layers of high thicknesses.

According to another advantageous embodiment, the particles form a bed of powder. This alternative is particularly advantageous for forming perovskite layers of low or medium thicknesses.

According to a particular embodiment, the target is a solid target formed of a film of organic or hybrid organic/inorganic perovskite. Such a film is deposited, for example, on a glass substrate. With such a target, it is possible to manufacture perovskite layers of low, medium and high thicknesses. This alternative is particularly advantageous for forming perovskite layers of low thicknesses. The target may be used for several successive depositions.

Advantageously, the target provided at step a) is obtained according to the following steps:

mechanosynthesis by co-milling a first material of formula AX and a second material of formula BX₂ in such a way as to obtain a powder of formula ABX₃,

pressing the powder of formula ABX₃ to obtain a solid target of formula ABX₃. According to an advantageous embodiment, the pressing of the solid target may be done while heating the powder.

Advantageously, before step c), the method comprises an additional step in the course of which the target is heated to a temperature ranging from 50° C. to 500° C. and is subjected to a pressure greater than 103 Pa. During this step, the target is not sublimated. This high pressure leads to interdiffusion of the elements that are present, and thus to the formation of particles of formula ABX₃ and/or to the agglomeration of the particles of the target. Thus, when the target is formed of particles of formula AX and particles of formula BX₂, it is possible to form in situ the ABX₃ phase in the target. This step is carried out under neutral atmosphere, for example under argon or under nitrogen. Such a step is, advantageously, carried out in the close space sublimation furnace, between step b) and step c).

Advantageously, during step c), the temperature difference between the target and the substrate is comprised between 10° C. and 350° C. and preferably between 50° C. and 200° C.

According to a particular alternative embodiment, step c) is carried out at a pressure P less than 1 Pa, and preferably less than 0.1 Pa.

According to another particular alternative embodiment, step c) is carried out under reducing atmosphere or under oxidising atmosphere.

Preferably, to form thick layers, a substrate will be chosen of which the thermal expansion coefficient is close to that of the organic or hybrid organic/inorganic perovskite layer to deposit. Close is taken to mean that their thermal expansion coefficients do not vary by more than 25%, and preferably they do not vary by more than 10%. Advantageously, the substrate is a TFT (thin film transistor) matrix deposited on a support for example made of glass, silicon or polyimide.

Advantageously, before step c), the method comprises an additional step in the course of which an intermediate layer, of nature identical or different to the organic or hybrid organic/inorganic perovskite layer, is deposited on the substrate in order to improve the quality of the main layer and/or the operation of the final device. The intermediate layer may:

play the role of seed layer, and/or

help crystallisation by favouring homoepitaxy or heteroepitaxy of the organic or hybrid organic/inorganic perovskite layer, and/or

ensure good electrical contact between the substrate and the organic or hybrid organic/inorganic perovskite layer, and/or

have optoelectronic properties, and/or

play the role of buffer layer in order to compensate for the difference in thermal expansion coefficient between the main layer and the substrate.

The method has at least one or several of the following advantages:

obtaining a target having directly the correct crystallographic phase,

forming organic or hybrid perovskites layers of low, intermediate or high thicknesses,

forming homogeneous layers within the thickness over the whole of the deposition,

forming organic or hybrid perovskite layers on large surface areas (of more than several tens of cm²),

controlling the speed of deposition over a very wide range (typically from several nm/min to several tens of μm/min), or even up to 1000 μm/h,

the method is carried out over reasonable times (preferably less than 5 h and, even more preferentially less than 2 h), since the deposition speed is correctly controllable between 1 nm/min and 10 am/min (from 0.1 nm/min to 50 am/min),

the method is implemented at moderate substrate temperatures (less than 350° C., preferably less than 250° C. and even more preferentially less than 200° C.), which makes it possible to use a wide range of substrates and/or supports (TFT matrix, silicon, glass, polymer, etc.),

deposition by CSS enables a high utilisation rate of the material (more than 80% and up to 90%, even up to 99% of sublimated material is deposited) compared to 20% to 50% for conventional evaporation deposition methods (typically 30% of the material is deposited for vacuum deposition methods), which thus reduces the manufacturing costs,

the method is reproducible and applicable at large scale,

the perovskite layers obtained have good purity (the CSS deposition is purer than the target, the impurities not generally being sublimated); in addition, by being placed below the melting temperature of the target, deposition by CSS purifies the material more than by evaporation,

having a very good utilisation rate of material (from 80% to 99%).

The invention also relates to a stack comprising a substrate and an organic or hybrid organic/inorganic perovskite layer obtained by a method such as described previously, the organic or hybrid organic/inorganic perovskite layer being made of MAPbBr₃ (preferably having a thickness comprised between 500 μm and 2 mm), Cs_{0.17}FA_{0.83}Pb(Br_{0.17}I_{0.3})₃ or MA₂AgBiBr₆.

The organic or hybrid organic/inorganic perovskite layer has, preferably, a thickness greater than or equal to 0.1 μm. For example, it has a thickness greater than 0.1 mm.

Preferably, the organic or hybrid organic/inorganic perovskite layer has a thickness of 1 to 10 mm. Such a layer is particularly interesting for X-ray or gamma ray detection applications.

The invention also relates to the use of a stack such as defined previously in the medical field (for example for X-ray detection) or in the photovoltaics field (for example in a perovskite cell or in a tandem module comprising a silicon heterojunction cell and a perovskite cell).

In particular, advantageously, a MAPbBr₃ layer will be used in the medical field, in particular for X-ray imaging or for the detection of gamma radiation. For example, the following will be used:

a MAPbBr₃ layer of thickness of around 200 μm for X-ray mammography,

a MAPbBr₃ layer of thickness of around 1 mm for X-ray radiography (hand, thorax, etc.),

a MAPbBr₃ layer of thickness of around 2 mm for scintigraphy.

A Cs_{0.17}FA₀₈₃Pb(Br_{0.17}I_{0.83})₃ layer of 400 nm could be used, for example, for manufacturing photovoltaic modules, in particular for manufacturing tandem modules with large forbidden energy gap such as tandems comprising a lower silicon heterojunction cell and an upper perovskite cell.

Other characteristics and advantages of the invention will become clear from the description complement that follows.

It goes without saying that this description complement is only given for the purposes of illustrating the subject matter of the invention and must not in any case be interpreted as a limitation of this subject matter.

### BRIEF DESCRIPTION OF THE DRAWINGS

The present invention will be better understood on reading the description of exemplary embodiments given for purely indicative purposes and in no way limiting and by referring to the appended drawings in which:

FIG. 1 represents, schematically in section, an organic or hybrid organic/inorganic perovskite layer deposited on a substrate according to a particular embodiment of the invention.

FIG. 2 represents, schematically in section, a stack comprising a support, a substrate and an organic or hybrid organic/inorganic perovskite layer according to a particular embodiment of the invention.

FIG. 3 represents, schematically in section, a stack comprising a support, a substrate, an intermediate layer and an organic or hybrid organic/inorganic perovskite layer according to a particular embodiment of the invention.

FIG. 4 represents, schematically, and in section, a CSS furnace according to a particular embodiment of the invention.

FIG. 5 represents, schematically, and in section, a susceptor and a cover of a CSS furnace according to a particular embodiment of the invention.

The different parts represented in the figures are not necessarily represented according to a uniform scale in order to make the figure more legible.

### DETAILED DESCRIPTION OF PARTICULAR EMBODIMENTS

Although this is in no way limiting, the invention is particularly interesting for the manufacture of electronic, optical or optoelectronic devices based on organic or hybrid organic/inorganic perovskite. For example, they may be LEDs, photovoltaic cells, detectors (infrared, X-ray radiation, gamma radiation, etc.), sensors (ferroelectric, pyroelectric), or actuators (piezoelectric).

The invention finds applications in the following fields:

detection of X-ray radiation in the medical field, notably for applications centred on mammography (detection of radiation centred around 18-20 keV, IEC 62220-1-2:2007 standard), imaging for conventional X-ray radiography (detection of radiation centred around 50 keV, RQA5, IEC 62220-1 standard, or centred on 90 keV, RQA9, IEC 62220-1 standard); in both these cases, the thickness of the organic or hybrid organic/inorganic perovskite layer is high to absorb a significant part of the radiation (typically from 0.1 mm to 2 mm, for example 1 mm),

photovoltaic, or UV, visible or infrared photodetector, or LED with low thicknesses of organic or hybrid organic/inorganic perovskite layer (typically 100 nm-2 μm, preferably several hundreds of nanometres),

detection of hard X-ray or gamma radiation with high thicknesses of organic or hybrid organic/inorganic perovskite (typically from 1 mm to 10 mm, preferably from 2 to 3 mm).

The method for manufacturing an organic or hybrid organic/inorganic perovskite layer 1 comprises the following steps:

providing a substrate 10 and an organic or hybrid organic/inorganic target 20,

b) positioning the substrate 10 and the target 20, in a close space sublimation furnace,

c) depositing an organic or hybrid organic/inorganic perovskite layer 1 on the substrate 10 by sublimation of the target 20.

The method makes it possible to form a perovskite (PVK) material layer 1 on a substrate 10. The thickness of the layer 1 may range from 10 nm to 10 mm as a function of the targeted applications. The composition of the perovskite layer is homogeneous whatever the thickness of the layer formed.

Generally, this invention applies to any perovskite of general chemical formula ABX₃, including mixed compositions such as:

A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ with y₂ and yₙ the respective proportions of A⁽²⁾ and A⁽ⁿ⁾, z₂ and zₘ the respective proportions of B⁽²⁾ and B^{(m)}, and x₂ and xₚ the respective proportions of X⁽²⁾ and X^{(p)}, and

A₂C¹⁺D³⁺X₆ (a material with double lattices).

For these different perovskite materials, A represents an organic compound, a mixture of organic compounds or a mixture of organic compound and inorganic compound. Organic compound is taken to mean any compound containing at least the element carbon and one or more of the following elements: hydrogen, halogen, oxygen, sulphur, phosphorous, silicon or nitrogen.

For example, A represents:
an organic molecule (for example CH₃NH₃⁺ (methylammonium MA) or CH(NH₂)₂⁺ (formamidinium FA)), or C(NH2)3⁺ (guanidinium GA)
a mixture of organic molecules (for example: MA₁₋ₓFAₓ with 0<x<1), or
a mixture of organic (for example MA, FA) and inorganic (for example Cs, Rb, K, Li, Na, etc.), (for example: Cs₁₋ₓFAₓ with 0<x<1) parts,

X is an anion, preferably a halide (for example Cl⁻, Br⁻, I⁻, F⁻, etc).

B may be an organic molecule (such as N-methyl-1,4-diazabicyclo[2.2.2]octane) (MDABCO) or N-hydroxy-N′-diazabicyclo[2.2.2]octonium (ODABC)), or an inorganic element (for example chosen from among Pb, Sn, Ge, Hg and Cd), or a mixture of organic molecules, inorganic elements or inorganic molecules and organic elements.

It is also possible to have from 2 to 5 elements on one of the sites, on two of the sites or on the three sites A, B and X. For example, it is possible to choose a material with X═ClₖBrₗI₁₋ₖ₋ₗ with 0≤k, l≤1 and 0≤k+l≤1.

According to a second advantageous alternative embodiment, the organic or hybrid organic/inorganic perovskite layer has for formula A₂C¹⁺D³⁺X₆.

The invention also applies to all other compositions belonging to perovskites:

materials of composition A₂C¹⁺D³⁺X₆ with C and D cations. C may be selected, for example, from among Ag, Au, TI, Li, Na, K, Rb and/or D may be selected, for example, from among Al, Ga, In, Sb, Bi and A and X chosen as previously,

materials of composition A₂B⁴⁺X₆ such as for example Cs₂Te⁴⁺I₆, materials of composition A₃B₂³⁺X₉ such as for example Cs₃Bi₂I₉, or A₃¹⁺B₂³⁺X₆¹ or other types of materials (chalcogenides, Rudorffites, etc.).

More generally materials of composition A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ.

Preferably, the following will be chosen:

MAPbBr₃, notably for medical applications such as mammography (energy 18 keV), and radiology (energy ^{˜}50 keV),

MA₂AgBiBr₆ notably for radiology (energy ^{˜}50 keV),

Cs_{0.17}FA_{0.83}Pb(Br_{0.17}I_{0.83})₃ notably for photovoltaics.

In the case where the target 20 is of formula ABX₃, the target 20 may be formed of a mixture of elementary particles A, B and X.

According to other embodiments, the target 20 of formula ABX₃ may be formed:

of a mixture of binary AX and BX₂ particles

of a mixture of AX, BX₂ and optionally ABX₃ particles,

of ABX₃ particles, which makes it possible to have directly the correct composition and the correct phase of the material to sublimate; these particles could, for example, be small monocrystals formed by liquid process, by Bridgman or other solution.

It is also possible to use more complex mixtures comprising more than two types of binary particles.

This is for example the case for mixed perovskites (multi-anion, multi-cation). For example to form MA₂AgBiBr₆, it is possible from a mixture of 3 binary powders: MABr, BiBr₃ and AgBr.

In the case where the target 20 is of formula A₂C¹⁺D³⁺X₆, the target may be composed:

of a mixture of binary AX, C¹⁺X and D³⁺X₃ particles,

of a mixture of AX, C¹⁺X and D³⁺X₃ and A′₂C¹⁺D³⁺X₆ particles,

of A₂C¹⁺D³⁺X₆ particles, which makes it possible to have directly the correct composition and the correct phase of the material to sublimate.

Similarly, in the case of A₃¹⁺B₂³⁺X₆¹⁻, it could be possible to start directly from a A₃¹⁺B₂³⁺X₆¹⁻ powder.

Other more complex compositions and/or compositions bringing into play a greater number of precursors may also be envisaged.

According to a particular embodiment, the target 20 forms a solid wafer (in other words the particles are agglomerated). Preferentially, the target 20 is a solid wafer of 1 to 10 mm thickness. For example, it has a thickness of 3 mm.

According to a particular embodiment, the target 20 is manufactured from ABX₃ crystals. The target may be either cut to the suitable dimensions from an ABX₃ crystal of greater dimensions, or by assembly of crystals of lower size (typically of millimetric or centimetric size). An additional step of cutting/polishing may be necessary during the assembly of crystals of lower size in order to ensure that they are indeed adjoining and form a flat paving. The crystal(s) used for the manufacture of the target may be formed by liquid process, by Bridgman or other solution. Crystal is taken to mean a monocrystal or a polycrystal (assembly of crystalline orientations).

According to another particular embodiment, the particles of the target 20 may form a bed of powders.

The characteristic size (or the particle size) of the particles forming the target 20 ranges, for example, from 10 nm to 1000 μm, and preferably from 20 μm to 100 am.

According to a particular embodiment, the target 20 is formed of an organic or hybrid organic/inorganic perovskite film deposited on a substrate, preferably compatible with high temperatures, for example on a glass substrate. This film may be constituted of ABX₃ type perovskite such as MAPbBr₃.

The film is continuous. The film is homogeneous.

The film of the target 20 may be obtained by CSS deposition from another target (called intermediate target) or by any other deposition method, such as for example by growth in solution or by evaporation.

Such a film may serve to form thin, intermediate or thick layers. The thickness of the film forming the target 20 is greater than or equal to the thickness of the layer to deposit 1. Preferably, the thickness of the film forming the target 20 is strictly greater than the thickness of the layer to deposit 1.

For example, a film of 1 to 10 mm, for example of 1.1 mm, may be used to form an organic or hybrid organic/inorganic perovskite layer 1 of 1 mm thickness.

In an alternative embodiment, the thickness of the film of the target 20 is at least 10 times and even more preferentially at least 100 times greater than the thickness of the layer to deposit 1. This embodiment is particularly advantageous for forming thin layers 1 (typically having a thickness less than 2 μm) of organic or hybrid organic/inorganic perovskite. Advantageously, the target 20 may serve for several depositions (for example for at least 3 depositions and preferentially for more than 20 depositions). The thickness of the target will have to be greater than the sum of the targeted deposition thicknesses.

The dimension of the target 20, formed of a bed of powder or of agglomerated particles, or instead a film, may range, for example, from 1 cm² to 1 m².

The dimension of the target 20 corresponds to the size of the deposition to carry out. For example, for a deposition of 40×40 cm², a target of same dimension is used.

The target 20 may be a single piece or an assembly of elements arranged in such a way as to form a paving of the size of the substrate 10. For example, for a deposition of 40×40 cm², a set of targets to form a paving of 40×40 cm² will be required. The substrate 10 on which the organic or hybrid organic/inorganic perovskite layer 1 is deposited may be made of glass, polyimide, for example made of Kapton®, or instead silicon. The substrate may be a matrix of TFT detectors or a matrix of CMOS detectors. The nature of the substrate depends on the targeted application and the temperatures used during the method.

The substrate 10 may itself be positioned on a support 11. For example, a TFT matrix on a polyimide support may be used.

According to an advantageous embodiment, the substrate 10 may be covered by an intermediate layer 12 (or sub-layer) or several intermediate layers.

At the end of step c), it is thus possible to obtain a stack comprising and preferably constituted by:

a substrate 10 and a perovskite layer 1 (FIG. 1), or

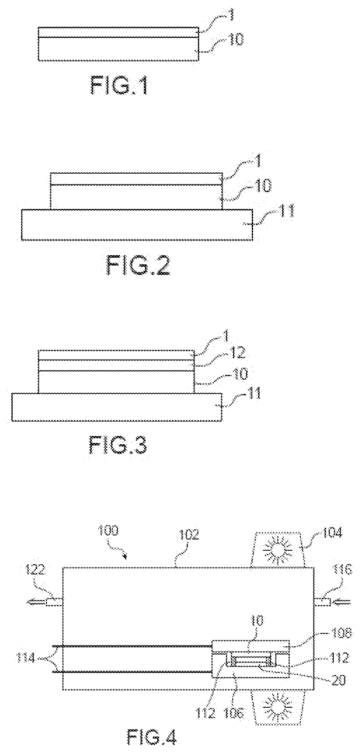

a support 11, a substrate 10 and a perovskite layer 1 (FIG. 2), or

a substrate 10, an intermediate layer 12 and a perovskite layer 1, or

a support 11, a substrate 10, an intermediate layer 12 and a perovskite layer 1 (FIG. 3).

In particular, the intermediate layer 12 may make it possible to form an electrode for an envisaged device and/or to provide a buffer layer with a thermal expansion coefficient (TEC) close to that of the perovskite layer to deposit.

According to a first alternative embodiment, the intermediate layer 12 is a layer of same nature as the organic or hybrid organic/inorganic perovskite layer to deposit, i.e. the intermediate layer 12 is a layer of formula ABX₃. This layer helps the growth of the layer formed at step c). It may notably play not only the role of seed layer, but also and especially to help crystallisation. The presence of the ABX₃ sub-layer on the substrate enables homoepitaxy of the main layer.

According to a second alternative embodiment, the intermediate layer 12 is made of ABX₃:D with D representing a doping element in the ABX₃ matrix. D may be an exogeneous element placed interstitially or substitutionally, a vacancy in the ABX₃ matrix or any other doping mechanism. D may for example be Bi³⁺ or Sn⁴⁺ placed substitutionally with respect to Pb²⁺. This doping makes it possible to obtain a doped (p or n) sub-layer different from the doping of the main layer (itself p, n doped or intrinsic). The role of this doped sub-layer is to ensure better electrical contact with the remainder of the device and/or to facilitate homoepitaxy of the main layer.

According to a third alternative embodiment, the intermediate layer 12 is made of a perovskite constituted of a partially or totally different element. For example a AB(X_{1-z}Y_{z})₃ sub-layer. An alloy (or a substitution of elements) is possible on one, several or all the sites A, B and X. It is also possible to envisage a CH₃NH₃PbX₃ type hybrid organic-inorganic sub-layer. The aim of the sub-layer is to exhibit different optoelectronic properties (forbidden energy gap, electron affinity, ionisation potential) in order to optimise the operation of the device.

According to a fourth alternative embodiment, the intermediate layer 12 is of totally different nature. It may be a crystalline layer or an amorphous layer. In this case, the envisaged role of the sub-layer is to play the role of buffer layer in order to compensate for the difference in thermal expansion coefficient between the main layer and the substrate. This layer will have to be chosen as a function of the substrate, its thermal expansion coefficient and its capacity to absorb stresses. For example, this sub-layer could be:

an organic or hybrid organic/inorganic perovskite of Ruddlesden-Popper or Dion Jacobson type comprising a part of organic nature which would make it possible to release the residual mechanical stresses linked to the differential TECs,

a crosslinked or non-crosslinked polymer layer,

a mixture of polymer(s) and perovskite(s), or small organic molecule(s) and perovskite(s),

a thin polycrystalline layer (<10 μm) of perovskite with or without crosslinking agent to maintain cohesion between the grains via ionic forces or Wan der Waals forces (examples: 1,6-diaminohexane dihydrochloride (CAS: 6055-52-3)),

a layer or multi-layer comprising ductile materials, type Zn, Pb, Al, Sn, etc.

a layer or multi-layer of any materials with intermediate TEC between those of the PVK and the substrate. The choice of the materials depends on the substrate/PVK pair deposited,

a multi-layer having materials under compressive/tensile stresses capable of compensating the tensile/compressive stresses due to thermal expansion. The choice of the materials depends on the substrate/deposited PVK layer pair.

The intermediate layer 12 may play one or several of the aforesaid roles/aims. For example, a ABX₃:D layer deposited by evaporation may both serve as electrical contact layer and enable homoepitaxy of the main layer.

If the nature of the sub-layer is different from the layer deposited during step c) but with a comparable lattice parameter, it may nevertheless favour the growth of this layer by heteroepitaxy.

The intermediate layer has a thickness less than the thickness of the layer deposited during step c). The thickness of the intermediate layer may range from several nanometres to several tens of microns. Typically, the thickness of the intermediate layer is 0.1% to 50%, for example 5%, of the thickness of the main deposition.

The sub-layer may be deposited in a continuous manner over the entire surface, or in a localised manner using direct deposition techniques (ink jet, screen printing, etc.) or by using lithography and photolithography techniques.

An intermediate perovskite layer 12 may be deposited by CSS (with a different target), by evaporation under vacuum, by liquid process or any other method for depositing inorganic and hybrid organic/inorganic PVK. As a non-limiting illustration, deposition by liquid process may be carried out by spin coating, in solvent, by pulsed laser deposition (PLD) or by chemical bath deposition (CBD).

Otherwise, the intermediate layer 12 may be deposited by methods for depositing thin layers under vacuum (evaporation, cathodic sputtering) or by deposition methods such as atomic layer deposition (ALD), electrodeposition, or growth in solution.

The intermediate layer 12 may also be deposited from the same target as that used for the main perovskite layer (step c). The composition of the target 20 then varies in its thickness (in other words, the target is formed of two different parts, each of the parts corresponding to a particular composition). The upper part of the target is constituted of the constituent elements of the intermediate layer 12, the lower part of the target is constituted of the constituent elements of the main layer 10. The upper part of the target is thinner (0.1 μm-100 μm) than its lower part (100 μm-10 mm). This bilayer target may be, for example, manufactured by compacting different powders on an already compacted target, by ion implantation in a target or other method.

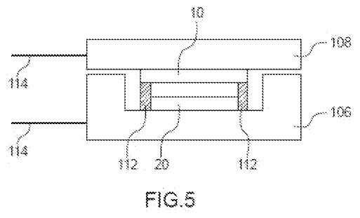

Step c) is carried out with a conventional CSS device 100 such as that represented for illustrative and non-limiting purposes in FIGS. 4 and 5. However, it could be any other CSS device.

The CSS furnace 100 comprises a reactor 102 around which is positioned a heating system. For example, it may involve lamps 104 (FIG. 4) or any other heating system (resistance for example).

The reactor 102 may be made of quartz, graphite, metal.

The reactor 102 may be tubular as in FIG. 1.

The furnace 100 also comprises a susceptor 106 (also called source block) and a cover 108 (also called substrate block). The susceptor 106 and the cover 108 are made of thermally conductive materials, being able to withstand pressure, vacuum and high temperatures. They are, preferably, made of graphite.

The substrate 10 and the target 20 are positioned between the susceptor 106 and the cover 108.

Preferably, the substrate 10 is in direct contact with the cover 108 which maintains its temperature at the set value.

The target 20 of PVK to deposit is arranged on the susceptor 106.

The substrate 10 is at a short distance from the target 20. Short distance is taken to mean a distance typically from 1 mm to 20 mm, preferentially from 1 mm to 7 mm, for example from 1 mm to 5 mm or from 3 mm to 5 mm. Notably, a distance of 2 mm could be chosen. A compromise will be chosen between a distance sufficiently close to have a high deposition speed and a sufficient distance to be able to maximise and maintain the thermal gradient in the course of deposition.

One or several spacers 112 made of thermally insulating material (for example glass, quartz, or alumina) serve to maintain the substrate 10 at a short distance from the target 20.

The cover 108 may be maintained pressed onto the substrate by a closing system in the susceptor 106 not represented (for example a screw or any other fastening system).

The susceptor 106 and the cover 108 each have a thermocouple 114 or any other system (pyrometer, etc.) for measuring and controlling their temperature.

A heating system (lamp, resistances, etc.) makes it possible to regulate the temperature of the susceptor 106 (T_{target}) and the cover 108 (T_{substrate}) in a range being able to go from 20° C. to 600° C. Temperature rise ramps are controllable in a range, for example, from 0.1° C./s to 10° C./s. The susceptor 106 (T_{target}) and the cover 108 (T_{substrate}) may be controlled by temperature ramps (or sequences of ramps), independently. Thus, it is possible to adjust the kinetics of sublimation of the target and the temperatures of condensation on the substrate so as to properly control the morphology of the layer according to the deposited thickness. In particular, these parameters may play on the dimension of the grains of the polycrystalline layer thus deposited on the substrate.

It is possible to add specific cooling devices for the cover 108 (for example, integrated piping for cooling liquid, protective screen against the radiation of the susceptor, radiators).

The device 100 is connected to a system with an intake for inert gas 116 (such as argon or N₂).

The device 100 may also be connected to an intake for oxidising gas (such as O₂) or to an intake for reducing gas (such as Hz).

The device 100 comprises a gas outlet 122, connected to a pumping system making it possible to attain a vacuum P_{furnace} ranging, for example, from 0.00001 Pa-1 Pa. The P_{furnace} value depends on the CSS furnace used.

During step c), the target is sublimated. The deposition by sublimation is carried out by heating the susceptor 106 and the cover 108 under vacuum.

During step c), the temperature of the substrate T_{sub} is less than the temperature of the target T_{target} in order to create a thermal gradient. During step c), the substrate is, advantageously, maintained at a controlled temperature. The same is true for the target.

The difference in temperature T_{target}−T_{sub} is from 10° C. to 350° C., preferably from 50° C. to 300° C. and even more preferentially from 100° C. to 250° C., for example 150° C.

The targeted temperatures depend on the material to deposit and are adjusted as a function of its phase diagram. For example, for the material MAPbBr₃, T_{target}=300° C. (±100° C.) and T_{substrate}=200° C. (±100° C.) could be chosen.

Temperature rise ramps comprised between 0.2° C./s and 10° C./s, for example 1° C./s, could for example be employed.

According to a first alternative embodiment, the deposition (sublimation) step is carried out at low pressure (typically less than 1 Pa). Advantageously, the pressure during step c) goes from 0.001 Pa to 1 Pa. For example, P_{furnace}=0.01 Pa may be chosen.

To carry out step c), it is possible to conduct neutral gas pump/purge cycles to evacuate the oxygen from the device 100 and place it at low pressure.

According to other alternative embodiments, to favour growth of the grains (germination, nucleation then growth), it may be interesting to work during step c) under oxidising atmosphere or under reducing atmosphere.

The oxidising atmosphere may be obtained by setting a low partial pressure (preferably from 0.1 to 10 Pa, for example 1 Pa) of Ar:O₂ (1 at %<O₂<10 at %)) during this step.

The reducing atmosphere may be obtained by setting a low partial pressure (preferably from 0.1 to 10 Pa, for example 1 Pa), of Ar:H₂ (1 at %<H₂<10 at %)) during this step.

The deposition time depends on the targeted thickness. To deposit thin layers (50 nm-5000 nm), the deposition times are of the order of 5 min to 2 h, for example 30 min. To deposit thick layers (50 μm-5000 am), the deposition times are of the order of 30 min to 8 h, for example 4h.

After step c), the perovskite layer formed is cooled. The cooling may be natural or controlled by ramps. A rapid cooling system (by water or cooling liquid in pipes inserted in the susceptor and cover) may also be envisaged.

According to a particular embodiment, the method comprises an additional high pressure step, between step b) and step c).

High pressure is taken to mean a pressure greater than 10³ Pa, for example of the order of 10⁵ Pa. This step is particularly advantageous in the case of the use of a target 20 comprising a mixture of powders, for example a mixture of AX and BX₂ powders. Indeed, this high pressure step makes it possible to obtain in situ the ABX₃ phase (thanks to the reaction AX+BX₂→ABX₃) before the sublimation of the target. A deposition of very good quality is thus obtained. This alternative is also particularly interesting in the case of a target 20 formed of a bed of powder then it makes it possible to agglomerate the particles and/or to compact the target.

The method may also comprise, before step a), a step in the course of which the target 20 of formula ABX₃ is manufactured.

The manufacture of the target requires shaping the particles in such a way as to form a target.

The particles may be obtained by milling or by co-milling.

The shaping may be carried out by pressing the particles in such a way as to obtain a solid target.

According to a first alternative embodiment, the particles forming the target are obtained by milling of a material of formula ABX₃. The milling step makes it possible to adjust the size of the particles. The material of formula ABX₃ may be obtained by crystalline growth, by chemical synthesis or any other synthesis method.

According to a second alternative embodiment, the particles forming the target are obtained by co-milling a first material of formula AX and a second material of formula BX₂.

According to a third alternative embodiment, the particles forming the target may be obtained by co-milling of three materials A, B and X.

The relative quantities of the different materials will be chosen in such a way as to form a target of formula ABX₃.

The milling or co-milling step may be carried out in a planetary ball mill.

Preferably, the particles forming the target 20 are obtained by mechanosynthesis. Mechanosynthesis consists in carrying out a very energetic co-milling of pure or pre-alloyed materials in a high energy mill, until a powder is obtained of which the particles are monophase or polyphase. For example, the AX and BX₂ mixture may lead to monophase particles (ABX₃) or an ABX₃+AX+BX₂ mixture being obtained.

An energetic milling is induced for example by:

an important mass of balls compared to the mass of powder (at least 2 times greater, for example 15 times greater), and/or

a high rotation speed (typically from 100 rpm to 700 rpm, for example 500 rpm), which depends on the mill used and the mass of balls and powders, and/or

a long milling time (between 10 min and 5 h, for example 1 h).

According to another embodiment, the particles are not co-milled before shaping the target. For example, when the powder comprises a mixture of different particles, for example AX and BX₂, it is possible of eliminate the co-milling phase. In this case, the formation of ABX₃ may be done:

either in the target before sublimation (in the CSS furnace) during the high pressure step according to the reaction AX+BX₂→ABX₃

or directly on the substrate according to the reaction AX+BX₂→ABX₃ after separate sublimation of AX and BX₂; It is advisable in this case to adjust the quantities of AX and BX₂ as a function of their sublimation temperature in order to maintain the final ABX₃ composition in the deposition. In a particular case of the invention, the composition of the target is not stoichiometric, but the deposition conditions and the relative speeds of deposition of the different precursors lead to a stoichiometric layer on the substrate on which the deposition is carried out.

The advantage of this alternative is to eliminate the milling step, thus leading to time and cost savings.

According to a particular embodiment, the powder of formula ABX₃ is pressed to form a solid wafer (or target). In other words, the particles are agglomerated or sintered.

A manual press may be used. The pressure to apply is comprised between 10¹ Pa·cm⁻² and 10⁸ Pa·cm⁻², for example 107 Pa·cm⁻².

In an alternative of the manual press, it is possible to press while heating (for example at T=250° C.±200° C.) to improve the compactness of the target and favour ABX₃ formation in the target.

The pressing while heating may notably be carried out by spark plasma sintering (SPS) which enables good compactness while maintaining a fine particle size (more homogeneous target).

According to another particular embodiment, the pressing step is not necessary if it is wished to use a bed of powders for the CSS method. In this case, the necessary quantity of powder (an AX/BX₂ mixture or instead ABX₃) is arranged directly on the susceptor 106 or on a support positioned on the susceptor 106. In the case of the AX/BX₂ mixture, it may be necessary to adjust the quantities of AX and BX₂ as a function of their sublimation temperature in order to maintain the final ABX₃ composition in the deposition.

The elimination of the pressing step represents a time and cost saving.

The mass of powder to use to form the target depends on the size and the desired thickness of the target, for example 4 to 5 g·cm⁻³ will be used.

The handling of powder is carried out, preferentially, in a glovebox under inert atmosphere (Ar or N₂) with a low level of O₂ and H₂O.

According to another alternative embodiment, the target may be manufactured from self-supported perovskite crystals having a lateral dimension ranging from several mm to several cm. These crystals may be monocrystals or polycrystals (several monocrystals intermingled with each other). These crystals, alone or abutted together side by side in mosaic form, may act as target. The crystal may have the composition of the perovskite layer to form. In the case where the target is constituted of at least two abutted crystals, their composition may be identical or different.

### ILLUSTRATIVE AND NON-LIMITING EXAMPLES OF EMBODIMENTS

Method for manufacturing a thick layer of MAPbBr₃.

In this example, firstly, an ABX₃ target of formula MAPbBr₃ of 10 g having a thickness of 1.1 mm and a surface of 25 cm² is manufactured.

The target is manufactured from particles of AX (MABr) and particles of BX₂ (PbBr₂).

The AX powders and BX₂ powders are commercially available. They have a purity greater than 99% (from 99% to 99.999%). Each of these powders is white.

The opening of the powder containers and the handling of the powders is carried out in a glove box under inert atmosphere (Ar or N₂) with a low level of O₂ and H₂O.

A defined mass of each powder is withdrawn in a stoichiometric manner so that the final composition of the mixture is ABX₃. Let m_{T} be the targeted mass of the ABX₃ target. The respective masses of AX (m_{AX}) and BX₂ (m_{BX}) to withdraw are thus:

m_{AX}=m_{T}×(M_{A}+M_{X})/(M_{A}+M_{B}+3M_{X})

m_{BX2}=m_{T}×(M_{B}+2M_{X})/(M_{A}+M_{B}+3M_{X})

with M_{A}, M_{B}, and M_{X} the molar masses of the elements A, B and X respectively.

Thus, to prepare a 10 g target of MAPbBr₃, masses of 2.338 g of MABr and 7.662 g of PbBr₂ will have to be withdrawn respectively. Their saturating vapour pressures at the targeted deposition temperature are not too far apart.

Optionally, the composition of the target may deviate from the exact stoichiometric composition in order to compensate for different sublimation speeds (due to different vapour pressures) of the compounds AX and BX₂. For example, to sublimate MAPbBr₃, it is possible from a (MABr)ₓ(PbBr₂) target with 0<1<x. The masses of AX and BX₂ are adjusted to obtain the desired x.

The two powders are placed in a milling cup (made of stainless steel, tungsten carbide or other) with a mass of milling balls m_{balls} such that m_{balls}≤m_{T}≤30×m_{balls} and preferably a mass of milling balls 15 times greater than the total mass m_{T} of powder. The choice of the size of cup is governed by the quantity of powder: the cup will, for example, be chosen so that all of the balls and powder fill around ⅓ of the cup. The cup is hermetically sealed to be placed in a planetary mill.

The rotation speed v_{R} is high (^{˜}300 rpm) and the milling time is around 1 h.

The powder thus obtained is next pressed to form a solid wafer. A manual press may be used. The order of magnitude of the pressure to apply is 107 Pa·cm⁻². The mass of powder used is around 4.5 g·cm⁻³.

The deposition of the thick layer of ABX₃ is next carried out in a conventional CSS furnace.

Ar pump/purge cycles of the furnace are carried out to evacuate oxygen, then the furnace is placed at low pressure (typically at a pressure 0.001 Pa<P<1 Pa, for example 0.1 Pa).

The deposition by sublimation is carried out by heating the susceptor 106 and cover 108, with T_{target}=300° C. (±100° C.) and T_{substrate}=200° C. (±100° C.) and the temperature rise ramps are comprised between 0.2° C./s and 10° C./s. The temperature rise ramps are, for example, 1° C./s.

A circular target and a spacer having a through hole of same dimension as the target are used.

The deposition time depends on the targeted thickness. For X-ray detection applications for the medical field, the targeted thicknesses are from 100 μm to 2 mm. Deposition times from 15 min to 5 h will consequently be chosen.

If a high pressure step is added, before step c), the following cycle may be carried out:

high pressure step: T_{target}^{˜}150° C., T_{substrate}^{˜}100° C., P_{furnace}=105 Pa of Ar (>10³ Pa), duration 30 min,

step c): T_{target}^{˜}300° C., T_{substrate}^{˜}200° C., P_{furnace}=0.1 Pa of Ar (<10 Pa), duration 30 min.

Method for manufacturing an X-ray detector for mammography (direct deposition):

Detectors used for mammography are typically 20×24 cm² and are optimised to detect radiation at 18-20 keV (IEC 62220-1-2:2007 standard).

For this application, it is possible to envisage a flexible substrate, for example a TFT matrix deposited on a polyimide support.

The manufacturing method comprises the following steps:

Providing a TFT matrix on polyimide; pitch of the pixels of the TFT matrix: 75 μm.

Depositing (or superposing) a layer being able to block electrons (for example NiOx or AlOx) by atomic layer deposition (ALD) or by any other method, for example by evaporation, cathodic sputtering, or instead deposition by liquid process; as an example, it is possible to deposit a polymer, such as PTAA or poly[bis(4-phenyl) (2,4,6-trimethylphenyl)amine), by spin-coating, or instead

A molecule, for example spiro-OMeTAD (CAS: 207739-72-8) by evaporation under vacuum.

Manufacturing 16 MAPbBr₃ targets of 5×6 cm² surface area and 0.7 mm thickness by mixing 36 g of MABr and 118 g of PbBr₂ in a milling cup with 600 g of steel balls for 2 h at 500 rpm then by successively pressing the 16 targets in an automatic press with a pressure of 3×10⁸ Pa.

Positioning the 16 targets in a graphite furnace of dimension 20×24 cm² at 5 mm from the substrate. The polyimide/TFT substrate may be fastened directly onto the cover (mechanical fastening) to prevent deflection due to its lack of rigidity.

Depositing a MAPbBr₃ layer of 500 μm thickness by CSS with the following conditions: 300° C. (target)/225° C. (substrate) for 1 h 30 at P=0.01 Pa.

Depositing (or superposing) a hole blocker layer (TiO₂:Mg, Nb₂O₅, CdS, C60, 60PCBM, SnO₂, ZnO, etc.) and an upper electrode (for example made of metal, conductive transparent oxide, etc.).

Method for Manufacturing an X-Ray Detector for Mammography (Indirect Deposition):

Detectors used for mammography are typically 20×24 cm² and are optimised for detecting radiation at 18-20 keV (IEC 62220-1-2:2007 standard).

For this application, it is possible to envisage a rigid substrate, for example a TFT matrix deposited on a glass support.

The manufacturing method comprises the following steps:

Providing a glass substrate (or any other substrate having properties of permeation to liquid water and water vapour).

Depositing a full field metal electrode capable of blocking electrons. For example 100 nm of Pt.

Manufacturing 16 MAPbBr₃ targets of 5×6 cm² surface area and 0.7 mm thickness by mixing 36 g of MABr and 118 g of PbBr₂ in a milling cup with 600 g of steel balls for 2 h at 500 rpm then by successively pressing the 16 targets in an automatic press with a pressure of 3×10⁸ Pa.

Positioning the 16 targets in a graphite furnace of dimension 20×24 cm² at 5 mm from the substrate. The glass substrate/Pt may be fastened directly onto the cover (mechanical fastening) to prevent deflection due to its lack of rigidity.

Depositing a MAPbBr₃ layer of 500 μm thickness by CSS with the following conditions: 300° C. (target)/225° C. (substrate) for 1 h30 at P=0.01 Pa.

Providing a TFT matrix on glass; pitch of the pixels of the TFT matrix: 75 μm.

mechanically and electrically coupling the glass substrate/Pt/500 μm of MAPbBr₃, on the TFT matrix on glass. The coupling will be achieved by means of a conductive adhesive (example: EPOTEK 301 and 320 mixture), conductive bumps, conductive ink deposited locally (for example by screen printing), an anisotropic conductive film (ACF) or any other technique known to those skilled in the art.

In an alternative, a matrix of pixels may be deposited on the MAPbBr₃ layer before coupling with the TFT matrix. In this case, the pixels of the TFT matrix are aligned with the pixels of the matrix on MAPbBr₃.

Method for Manufacturing an Imager for X-Ray Radiography (Hand, Thorax, Joint, Fracture, Etc.):

Imagers for X-ray radiography are of dimension 42×42 cm² and the radiation used is centred around 50 keV (RQA5, IEC 62220-1 standard).

The method comprises the following successive steps:
Providing a rigid (glass) or flexible (polyimide) support on which is deposited a TFT matrix (pitch of the pixels 180 μm) and an (or a superposition of an) electron blocker layer
Preparing 36 square targets of 7×7 cm² of 1 mm thickness (i.e. around 800 g of powder: 300 g MABr, 515 g PbBr₂). Co-milling the powders with a mass of balls 10 times greater for 1 h at 300 rpm
Positioning the targets and the support/substrate stack in the CSS furnace, a spacer maintaining the substrate at 2 mm from the targets
Depositing an active layer of 0.8 mm of MAPbBr₃ with the following conditions: 300° C. (target)/225° C. (substrate) for 2 h at P=0.01 Pa
Depositing (or superposing) a hole blocker layer (TiO₂:Mg, Nb₂O₅, CdS, etc.) and an upper electrode (for example made of metal, conductive transparent oxide, etc.).

Method for manufacturing an imager for real time X-ray imaging—implant of an arterial endoprosthesis (cardiac “stent”) for example:

Imagers for real time X-ray imaging are of reduced dimensions (21×21 cm²) but the radiation used of 60 keV is more energetic (RQA9, IEC 62220-1 standard). The architecture of the detector is similar (by reducing the dimensions of the targets and furnace to adapt to the targeted size), the thickness of the MAPbBr₃ layer is around 1.2 mm. The thickness of the targets is thus 1.5 mm and the deposition time around 2 h 30.

Method for manufacturing a photovoltaic module based on inorganic PVK (notably the upper part of a Si heterojunction/PVK tandem module with wide forbidden energy gap):

The relatively low targeted thicknesses of the materials (between 100 nm and 2 μm) require shorter deposition times and lower deposition temperatures. The deposition being thinner, it may be obtained from a bed of powders. Furthermore, the surface area of the substrate (and thus of the whole of the furnace and susceptor) is greater: typically 60 cm×120 cm. It is possible for example (non-restrictive example) to consider Cs_{0.17}FA_{0.83}Pb(Br_{0.17}I_{0.83})₃ as absorber material. The method describes uniquely the deposition of the different layers; the standard modularised part (by P1-P3-P3 interconnection for example) is not described.

The method is carried out in the following manner:
providing a substrate: a module with high performance Si heterojunction terminated by a layer of ITO
depositing an electron transport layer (type NiO deposited by liquid process, ALD or other)
manufacturing the target by co-milling, at 500 rpm, three CsBr, FAI and PbI₂ powders in order to obtain a powder comprising the elements in the targeted stoichiometry
manufacturing 50 targets of 12×12 cm² of 1 mm thickness. The targets may serve for several depositions
depositing the Cs_{0.17}FA₀₈₃Pb(Br_{0.17}I_{0.83})₃ layer by CSS: T_{target}˜275° C. (±50° C.), T_{substrate}˜200° C. (±50° C.), P_{furnace}=0.1 Pa of Ar (<10 Pa), duration 15 min; sublimation of 400 nm of Cs_{0.17}FA_{0.83}Pb(Br_{0.17}I_{0.83})₃
depositing a hole transport layer (for example of spiro-OMeTAD (CAS: 207739-72-8) or PTAA (poly[bis(4-phenyl) (2,4,6-trimethylphenyl)amine)) type
depositing an electrode made of ITO, an anti-reflective layer and gates.

Method for manufacturing a scintillator for detecting gamma radiation for medical applications (example of scintigraphy, radiation at 140 keV):

Scintillators are devices for indirectly detecting radiation: said radiation is transformed into visible light which is in turn captured by a photodetector. The use of a scintillator may also be made for the detection of X-ray (10²-10⁵ eV) or gamma (>10⁵ eV) radiation. An example of scintillator for gamma detection will be given here, but the principle is the same for X-ray detection.

Gamma radiation detectors are useful in numerous fields: medical (tomography) but also in the industrial field (non-destructive testing, security systems), the geophysics field (analysis of the nature of the ground for oil exploration), the field of public safety (control of luggage, vehicles), the field of fundamental research.

The method for manufacturing a scintillator for detecting gamma radiation for medical applications (example of scintigraphy, radiation at 140 keV) will now more particularly be described. The imagers are 40×40 cm².

The method comprises the following steps:
Providing a TFT matrix on a rigid support (glass) on which is deposited a matrix of organic or amorphous silicon photodetectors
Depositing a MAPbBr₃ layer of 2 mm thickness by CSS. The same deposition method is used as for the X-ray detector for mammography (paving of 25 targets 6×6 cm²) of 2.5 mm thickness. The deposition time is comprised between 3 h and 4 h
Depositing by cathodic sputtering an aluminium protective layer.

### REFERENCES

[1] Dunlap-Shohl et al., Synthetic approaches for halide perovskite thin films. Chemical Reviews, 2018. 119(5): p. 3193-3295.
[2] Wang et al., Structural and photophysical properties of methylammonium lead tribromide (MAPbBr₃) single crystals. Scientific Reports, 2017. 7(1): p. 1-14.
[3] Ye et al., Metal-free three-dimensional perovskite ferroelectrics. Science, 2018. 361(6398): p. 151-155.
[4] WO 2017/031193 A1

1. A method for depositing by close space sublimation an organic or hybrid organic/inorganic perovskite layer on a substrate comprising the following steps:
a) providing a substrate and an organic or hybrid organic/inorganic target,
b) positioning the substrate and the target, in a close space sublimation furnace,
c) depositing an organic or hybrid organic/inorganic perovskite layer on the substrate by sublimation of the target.

2. The method according to claim 1, wherein the organic or hybrid organic/inorganic perovskite layer has for formula ABX₃
with
A an organic compound, a mixture of organic compounds or a mixture of organic compound and inorganic compound,
B a single inorganic element, an organic molecule or a mixture of several inorganic elements and/or organic molecules,
and X an anion.

3. The method according to claim 2, wherein the organic or hybrid organic/inorganic perovskite layer is made of MAPbBr₃.

4. The method according to claim 1, wherein the organic or hybrid organic/inorganic perovskite layer has for formula A₂C¹⁺D³⁺X₆
with A an organic compound, a mixture of organic compounds or a mixture of organic compound and inorganic compound,
C and D cations,
and X an anion.

5. The method according to claim 4, wherein the organic or hybrid organic/inorganic perovskite layer has for formula MA₂AgBiBr₆.

6. The method according to claim 1, wherein the organic or hybrid organic/inorganic perovskite layer has for formula A⁽¹⁾_{1-(y2+ . . . +yn)}A⁽²⁾_{y2} . . . A⁽ⁿ⁾_{yn}B⁽¹⁾_{1-(z2+ . . . +zm)}B⁽²⁾_{z2} . . . B^{(m)}_{zm}X⁽¹⁾_{3-(x2+ . . . +xp)}X⁽²⁾ₓ₂ . . . X^{(p)}ₓₚ
with A an organic compound, a mixture of organic compounds or a mixture of organic compound and inorganic compound,
B a single inorganic element, an organic molecule or a mixture of several inorganic elements and/or organic molecules,
X an anion.

7. The method according to claim 6, wherein the organic or hybrid organic/inorganic perovskite layer has for formula Cs_{0.17}FA_{0.83}Pb(Br_{0.17}I_{0.83})₃.

8. The method according to claim 2, wherein the target comprises particles of the same formula as the deposited layer.

9. The method according to claim 2, wherein the target comprises a mixture of binary particles of different natures or a mixture of binary particles of different natures and tertiary particles.

10. The method according to claim 8, wherein the target provided at step a) is obtained according to the following steps:
mechanosynthesis by co-milling of a first material of formula AX and a second material of formula BX₂ in such a way as to obtain a powder of formula ABX₃,
pressing the powder of formula ABX₃ to obtain a solid target of formula ABX₃.

11. The method according to claim 8, wherein the target provided at step a) is obtained according to the following steps:
manufacturing a material of formula ABX₃ by chemical synthesis, crystalline growth or any other synthesis mechanism then milling to obtain a powder of formula ABX₃,
pressing the powder of formula ABX₃ to obtain a solid target of formula ABX₃.

12. The method according to claim 1, wherein, before step c), the method comprises an additional step in the course of which the target is heated to a temperature ranging from 50° C. to 500° C. and is subjected to a pressure greater than 103 Pa.

13. The method according to claim 1, wherein step c) is carried out at a pressure P less than 1 Pa.

14. The method according to claim 1, wherein step c) is carried out under reducing atmosphere or under oxidising atmosphere.

15. The method according to claim 1, wherein that, before step c), the method comprises a step in the course of which an intermediate layer, of nature identical or different to the organic or hybrid organic/inorganic perovskite layer, is deposited on the substrate.

16. The method according to claim 1, wherein the temperature difference between the target and the substrate is comprised between 10° C. and 350° C.

17. The method according to claim 1, wherein the thickness of the deposited organic or hybrid organic/inorganic perovskite layer is comprised between 1 mm to 10 mm.

18. The method according to claim 1, wherein the substrate (10) is at a distance from 1 to 5 mm from the target (20).

19. A stack comprising a substrate and an organic or hybrid organic/inorganic perovskite layer obtained by the method according to claim 1, the organic or hybrid organic/inorganic perovskite layer being made of MAPbBr₃, Cs_{0.17}FA_{0.83}Pb(Br_{0.17}I_{0.83})₃ or MA₂AgBiBr₆ and having a thickness of 1 mm to 10 mm.

20. Use of a stack such as defined in claim 19, for the detection of X-rays and gamma rays.
